(19) United States
(12) Patent Application Publication
(10) Pub. No.: US 2025/0046366 A1
(43) Pub. Date: Feb. 6, 2025

(54) PULSE GENERATOR AND MEMORY DEVICE COMPRISING THE SAME

(71) Applicant: SAMSUNG ELECTRONICS CO., LTD., Suwon-si (KR)

(72) Inventors: Kiryong KIM, Suwon-si (KR); Inhak Lee, Suwon-si (KR); Jaesung Choi, Suwon-si (KR)

(73) Assignee: SAMSUNG ELECTRONICS CO., LTD., Suwon-si (KR)

(21) Appl. No.: 18/420,456

(22) Filed: Jan. 23, 2024

(30) Foreign Application Priority Data
Aug. 1, 2023 (KR) 10-2023-0100451

(51) Int. Cl. G11C 11/418; G11C 11/419

(52) U.S. Cl. CPC G11C 11/418; G11C 11/419

(57) ABSTRACT

A memory device includes a cell array including a plurality of static random-access memory (SRAM) cells; a row decoder configured to drive a plurality of word lines of the plurality of SRAM cells based on a row address; a data input/output circuit connected to a plurality of bit lines of the cell array and connected to a sub-power line configured to supply cell voltage to the plurality of SRAM cells; and a word line pulse generator configured to generate a word line pulse with a first pulse width that varies based on the row address and to provide the word line pulse to the row decoder.

### CROSS-REFERENCE TO RELATED APPLICATIONS

This application claims priority under 35 U.S.C. § 119 to Korean Patent Application No. 10-2023-0100451 filed on Aug. 1, 2023, in the Korean Intellectual Property Office, the disclosure of which is incorporated by reference herein in its entirety.

### BACKGROUND

This application is related to a semiconductor memory device, and more specifically, to a pulse generator using a row address tracking function and a memory device including the same.

Semiconductor memory devices may include static random-access memory (SRAM), which stores data using latches, or dynamic random-access memory (DRAM), which stores data using capacitors. SRAM is difficult to integrate compared to DRAM, so the capacity provided in the same area is small, but SRAM has advantages such as high-speed operation, low power consumption, and ease of control, so it is used in memories that require high-speed access, such as caches.

SRAM includes a plurality of bit cells arranged in rows and columns. Each bit cell includes a latch connected to a corresponding word line and a corresponding bit line. During a write or read operation, a word line pulse is applied to the word line to select the bit cell. And during a write operation, the cell voltage or write assist voltage VDDA is applied from a write assist circuit to adjust the power voltage of the bit cell.

Advances in micro-processing are making it possible to integrate more elements per unit area of a semiconductor device. In particular, as miniaturization increases, the resistance of metal lines connecting elements of semiconductor devices increases. As the resistance value of the metal line increases, the signal transmission characteristics change depending on the distance. To compensate for these transmission characteristics and ensure reliability, a method of increasing the read margin or write margin is used. However, increasing the read margin or write margin ultimately reduces the power efficiency of the memory device.

### SUMMARY

One or more embodiments of the present disclosure provide a pulse generator for a memory device whose pulse width varies depending on the position of the selected row. Also, one or more embodiments provide a memory device that can provide high power efficiency by using a pulse generator whose pulse width varies depending on the position of the selected row.

According to an aspect of an embodiment, a memory device includes: a cell array including a plurality of static random-access memory (SRAM) cells; a row decoder configured to drive a plurality of word lines of the plurality of SRAM cells based on a row address; a data input/output circuit connected to a plurality of bit lines of the cell array and connected to a sub-power line configured to supply cell voltage to the plurality of SRAM cells; and a word line pulse generator configured to generate a word line pulse with a first pulse width that varies based on the row address and to provide the word line pulse to the row decoder.

According to an aspect of an embodiment, a pulse generator of a static random-access memory (SRAM) device, includes: a pulse generation circuit configured to generate a first pulse signal based on a write enable signal or a read enable signal; a row address tracking circuit configured to generate a second pulse signal by delaying the first pulse signal based on a row address; and a logic gate unit configured to generate a word line pulse or a write assist pulse of the SRAM device by performing logical multiplication operation of the first pulse signal and the second pulse signal.

According to an aspect of an embodiment, a memory device includes: a cell array including a plurality of static random-access memory (SRAM) cells; a row decoder configured to drive a plurality of word lines of the plurality of SRAM cells based on a row address; a data input/output circuit connected to a plurality of bit lines of the cell array; a write assist circuit configured to supply a cell voltage or a write assist voltage to the plurality of SRAM cells through a sub power line; a word line pulse generator configured to generate a word line pulse with a first pulse width that varies based on the row address to provide the word line pulse to the row decoder; and a write assist pulse generator configured to generate a write assist pulse with a second pulse width that varies based on the row address.

### BRIEF DESCRIPTION OF THE DRAWINGS

The above and other aspects and features of the present disclosure will become apparent by describing in detail embodiments thereof with reference to the accompanying drawings, in which:

FIG. 1 is a block diagram showing a memory device according to an embodiment;

FIG. 2 is a diagram showing the detailed configuration of the cell array of FIG. 1;

FIG. 3 is a circuit diagram showing the structure of a word line pulse generator according to an embodiment;

FIG. 4 is a circuit diagram showing the structure of the word line pulse generator shown in FIG. 3;

FIG. 5 is a waveform diagram showing the operating characteristics of the word line pulse generator of FIG. 4;

FIG. 6 is a table showing the power reduction effect by the word line pulse RowCK of an embodiment;

FIG. 7 is a circuit diagram showing the structure of a word line pulse generator according to another embodiment;

FIG. 8 is a circuit diagram showing the structure of the word line pulse generator shown in FIG. 7;

FIG. 9 is a circuit diagram showing the structure of a write assistance pulse generator according to an embodiment;

FIG. 10 is a circuit diagram showing the structure of the write assist pulse generator shown in FIG. 9;

FIG. 11 is a waveform diagram showing the operating characteristics of the write assist pulse generator of FIG. 10;

FIG. 12 is a table showing the power reduction effect by the write assist pulse WAST_EN of an embodiment;

FIG. 13 is a circuit diagram showing another implementation method of the word line pulse generator or the write assist pulse generator with the row address tracking function of an embodiment;

FIG. 14A and FIG. 14B are circuit diagrams showing embodiments of the digital control delay line of FIG. 13, respectively; and

FIG. 15 is a block diagram exemplarily showing the structure of a mobile device including the memory device of an embodiment.

### DETAILED DESCRIPTION

It is to be understood that both the foregoing general description and the following detailed description are exemplary. Reference signs are indicated in detail in embodiments, examples of which are indicated in the reference drawings. Wherever possible, the same reference numbers are used in the description and drawings to refer to the same or like parts.

Below, aspects and advantages of the present disclosure will be explained using SRAM as an example. However, those skilled in the art will readily understand other advantages and capabilities of the present disclosure based on what is described herein. The present disclosure may be implemented or applied through other embodiments. Moreover, the detailed description may be modified or changed according to viewpoints and applications without significantly departing from the scope, technical spirit and other purposes of the present disclosure.

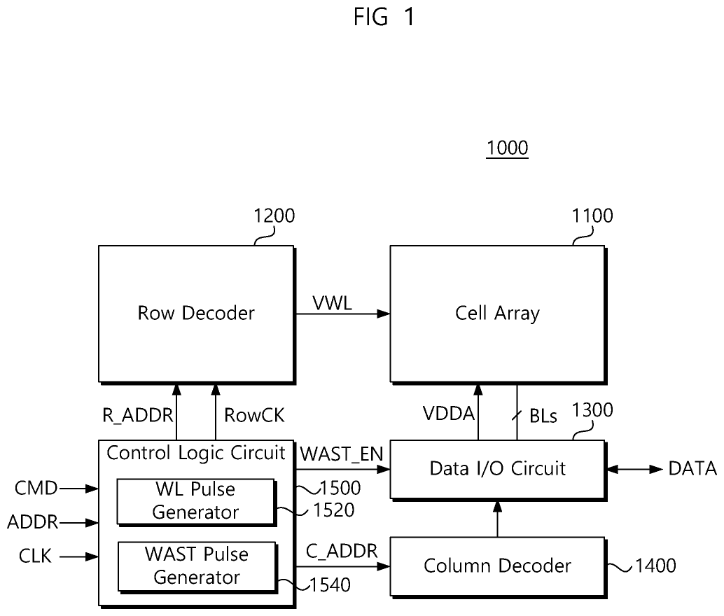

FIG. 1 is a block diagram showing a memory device according to an embodiment. Referring to FIG. 1, the memory device 1000 may include a cell array 1100, a row decoder 1200, a data input/output circuit 1300, a column decoder 1400, and a control logic circuit 1500.

The cell array 1100 may include a plurality of SRAM cells or bit cells that store data. Each of the plurality of bit cells included in the cell array 1100 may be disposed at a point where a plurality of word lines WLs and a plurality of bit lines BLs intersect. For example, each of the bit cells may be connected to a corresponding word line among the plurality of word lines WLs. Each of the bit cells may be connected to a corresponding bit line among the plurality of bit lines BLs. Bit cells can be selected by the word line voltage VWL provided to the selected word line. Bit cells can store or output data using the cell voltage VDDA. In particular, during a write operation, the bit cells are driven by receiving a cell voltage VDDA provided from a write assist circuit to improve write performance.

The row decoder 1200 decodes the row address R_ADDR and selects one of the plurality of word lines WLs according to the decoding result. During a write operation, the row decoder 1200 will transfer the word line voltage VWL in the form of a pulse to one word line selected by the row address R_ADDR. And the row decoder 1200 will supply the word line voltage VWL at the low level ‘L’ to the word lines unselected by the row address R_ADDR. In particular, the row decoder 1200 provides a word line voltage VWL to the selected word line using the word line pulse RowCK generated by the word line pulse generator 1520 of the control logic circuit 1500.

The data input/output circuit 1300 is connected to the cell array 1100 through a plurality of bit lines BLs. The data input/output circuit 1300 writes data to the selected bit cell through a bit line during a write operation. During a read operation, the data input/output circuit 1300 may output the sensed data to the outside through a bit line. For example, the data input/output circuit 1300 may include a write driver and a sense amplifier. In particular, the data input/output circuit 1300 may include the write assist circuit that adjusts the cell voltage VDDA to improve write performance during a write operation. The write assist circuit may adjust the drop time of the cell voltage VDDA according to the row address in response to the write assist enable signal WAST_EN.

The column decoder 1400 receives the column address C_ADDR from the control logic circuit 1500. The column decoder 1400 decodes the column address C_ADDR. The column decoder 1400 selects a bit line corresponding to the column address C_ADDR among the plurality of bit lines BLs connected to the cell array 1100 according to the decoding result. For example, the column decoder 1400 connects the bit line BL corresponding to the column address C_ADDR to a write driver or a sense amplifier.

The control logic circuit 1500 receives a command CMD, an address ADDR, and a clock signal CLK from an external device (e.g., a host or CPU) of the memory device 1000. The control logic circuit 1500 may control the operation of the memory device 1000 based on the clock signal CLK received from an external device. The control logic circuit 1500 may extract the row address R_ADDR from the received address ADDR and transmit it to the row decoder 1200, and transmit the column address C_ADDR to the column decoder 1400.

In particular, the control logic circuit 1500 includes a word line pulse generator 1520 and a write assist pulse generator 1540. The control logic circuit 1500 may further include a command decoder for decoding the received command CMD. The control logic circuit 1500 decodes the command CMD and activates the word line pulse generator 1520 or the write assist pulse generator 1540 during a write operation or a read operation.

The word line pulse generator 1520 generates a word line pulse RowCK whose pulse width varies depending on the row address R_ADDR during a write operation or a read operation. When a bit cell close to the data input/output circuit 1300 (hereinafter referred to as a Near Cell) is selected, the word line pulse generator 1520 generates a word line pulse RowCK with a relatively narrow pulse width. On the other hand, when a bit cell located at a long distance from the data input/output circuit 1300 (hereinafter referred to as a Far Cell) is selected, the word line pulse generator 1520 generates a word line pulse RowCK with a relatively wide pulse width. In other words, the word line pulse generator 1520 generates a word line pulse RowCK whose pulse width varies depending on the row address R_ADDR. Then, the row decoder 1200 will generate the word line voltage VWL using the word line pulse RowCK provided by the word line pulse generator 1520.

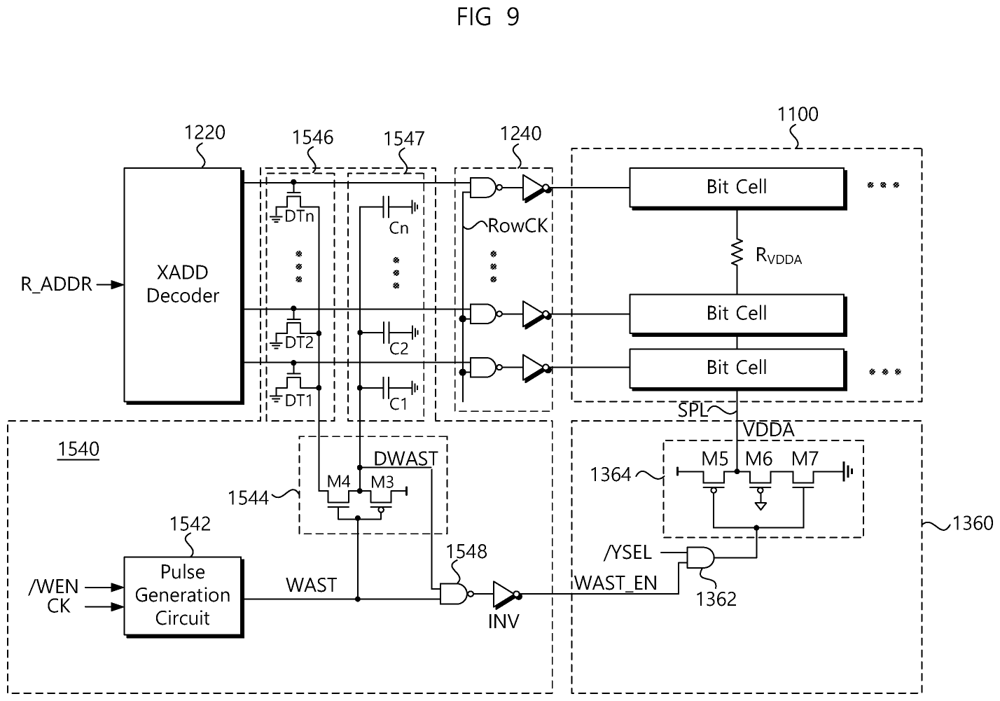

The write assist pulse generator 1540 generates a write assist pulse WAST_EN that defines an activation period of the write assist circuit 1360 (see FIG. 9, described later). The write assist pulse generator 1540 generates a write assist pulse WAST_EN whose pulse width varies depending on the row address R_ADDR. When the near cell is selected, the write assist pulse generator 1540 generates the write assist pulse WAST_EN with a relatively narrow pulse width. On the other hand, the word line pulse generator 1520 generates the write assist pulse WAST_EN with a relatively wide pulse width when the far cell is selected. That is, the write assist pulse generator 1540 may generate the write assist pulse WAST_EN whose pulse width varies depending on the row address R_ADDR. Then, the write assist circuit will drop the cell voltage VDDA during the period corresponding to the write assist pulse WAST_EN.

In the above, the configurations of the memory device 1000 that generates the word line pulse RowCK or the write assist pulse WAST_EN whose pulse width is adjusted according to the row address R_ADDR were briefly described. When memory cells are selected based on the word line pulse RowCK, the bit line development size of the near cell and far cell can be kept constant. Accordingly, power consumption due to excessive development of the bit line occurring in the near cell can be reduced. In addition, by varying the drop section of the cell voltage VDDA based on the write assistance pulse WAST_EN according to the row address R_ADDR, power consumption due to excessive drop of the cell voltage VDDA occurring in the near cell can be reduced.

The memory device 1000 may be implemented with SRAM, but is not limited thereto. For example, in some embodiments, the memory device 1000 may include one of Dynamic Random Access Memory (DRAM), NAND Flash Memory, NOR Flash Memory, Resistive Random Access Memory (RRAM), and Ferroelectric Random Access Memory (FRAM), Phase Change Random Access Memory (PRAM), or Magnetic Random Access Memory (MRAM).

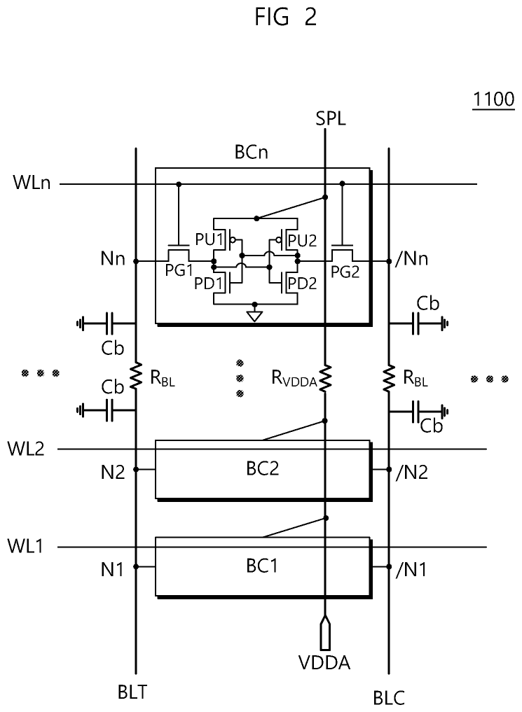

FIG. 2 is a diagram showing the detailed configuration of the cell array of FIG. 1. Referring to FIG. 2, bit cells corresponding to one column are shown. Each of the bit cells BC1 to BCn is formed at a point where the word lines WL1 to WLn and the bit line pairs (BLT, BLC) intersect. Hereinafter, the characteristics of each of the bit cells BC1 to BCn−1 will be described, taking the configuration of the bit cell BCn as an example.

The bit cell BCn may include a plurality of transistors PG1, PG2, PU1, PU2, PD1 and PD2 connected to the bit line pair (BLT, BLC) or word line WLn. The plurality of transistors may include a pair of transfer transistors (PG1, PG2), a pair of pull-up transistors (PU1, PU2), and a pair of pull-down transistors (PD1, PD2). The pull-up transistors PU1 and PU2 may be PMOS transistors, and the pull-down transistors PD1 and PD2 and the transfer transistors PT1 and PT2 may be NMOS transistors.

The gates of the transfer transistors PG1 and PG2 may be connected to the word line WLn, and the drains may be connected to the bit line pairs BLT and BLC, respectively. The sources of the pull-up transistors PU1 and PU2 are connected to the sub power line SPL that supplies the cell voltage VDDA. Sources of the pull-down transistors PD1 and PD2 are connected to ground. The first pull-up transistor PU1 and the first pull-down transistor PD1 form one inverter, and the second pull-up transistor PU2 and the second pull-down transistor PD2 form another inverter. The input and output terminals of each inverter are interconnected to form a latch that can store data.

The transfer transistors PG1 and PG2 are turned on by the word line voltage VWL supplied to the word line WLn, thereby enabling reading or writing of the bit cell BCn. During a read operation, the data stored in the bit cell BCn can be output by a sense amplifier sensing the voltage level developed in the bit line pair (BLT, BLC). During a write operation, the latch of the bit cell BCn is set to ‘0’ or ‘1’ by the data signal transmitted from the write driver to the bit line pair (BLT, BLC). At this time, a write assist circuit that lowers the cell voltage VDDA is activated to increase the write performance of the latch. Then, the level of the cell voltage VDDA can decrease, and the write performance of the latch can be improved.

Generally, each bit line pair (BLT, BLC) is formed using a metal pattern for the bit line formed on the same semiconductor layer. The bit line voltage provided through the write driver will be transmitted to the latch of the bit cell that crosses any one selected among the word lines WL1 to WLn. For example, if the word line WLn is selected, data will be written to the bit cell BCn through the nodes (Nn, /Nn) where the bit line pair (BLT, BLC) and the bit cell BCn intersect. Likewise, when the word line WL1 is selected, data will be written to the bit cell BC1 through the nodes (N1, /N1) where the bit line pair (BLT, BLC) and the bit cell BC1 intersect. During a read operation, the level of the bit line pair (BLT, BLC) developed by the stored data of the selected bit cells is sensed by a sense amplifier.

In addition, the cell voltage VDDA, which will be used as a driving power source for each of the bit cells BC1 to BCn, is transmitted to each bit cells BC1 to BCn through the sub power line SPL. The cell voltage VDDA is generated in the write assist circuit.

Bit line pairs (BLT, BLC) or sub power lines SPL are formed as conductive lines. For example, a bit line pair (BLT, BLC) or a sub power line SPL can be formed using a metal line. However, as the process becomes more refined, the resistance of the bit line pair (BLT, BLC) or sub-power line SPL increases. Each bit line pair (BLT, BLC) will have a greater resistance RBL as it moves away from the data input/output circuit 1300. The resistance RVDDA of the sub power line SPL will also have a larger resistance value as it moves away from the data input/output circuit 1300. And the bit line pair (BLT, BLC) or sub power line SPL includes parasitic capacitance Cb. Accordingly, the size of the voltage drop or time constant that occurs varies depending on the length of the bit line pair (BLT, BLC) or the sub power line SPL.

By applying the word line pulse RowCK or write assist pulse WAST_EN whose pulse width is adjusted according to the row address R_ADDR, the bit line voltage changes in near cells and far cells can be controlled to be constant or to a level that minimizes power consumption. In other words, during a read operation through the word line pulse RowCK adjusted according to the row address R_ADDR, in the case of a near cell, the development time of the bit line can be provided shorter than that of a far cell. Accordingly, the power consumed for bit line recovery can be reduced. In addition, during a write operation, the drop section of the cell voltage VDDA based on the write assistance pulse WAST_EN can be varied according to the row address R_ADDR. Then, power consumption due to excessive drop in cell voltage VDDA occurring in the near cell can be reduced.

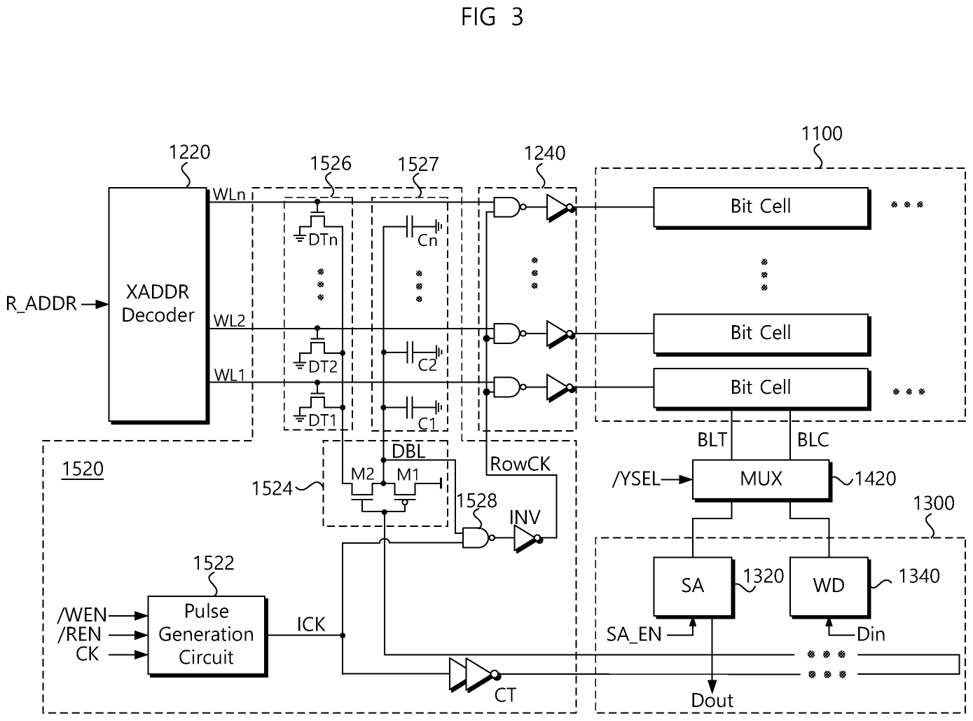

FIG. 3 is a circuit diagram showing the structure of a word line pulse generator according to an embodiment. Referring to FIG. 3, the word line pulse generator 1520 generates a word line pulse RowCK with a pulse width that varies depending on the row address R_ADDR. The word line voltage VWL is provided to the bit cells of the selected row based on the word line pulse RowCK. Here, since the cell array 1100 is substantially the same as that of FIG. 2, its description will be omitted. The word line pulse generator 1520 may be provided as part of the control logic circuit 1500 of FIG. 1.

A row address decoder 1220 and a pulse transfer circuit 1240 may be included as part of the row decoder 1200. The row address decoder 1220 decodes the input row address R_ADDR and activates the selected word line. For example, when the row address R_ADDR corresponds to the word line WL2, the row address decoder 1220 sets the word line WL2 to high level ‘H’ and sets the remaining word lines WL1, WL3 to WLn to low level ‘L’.

The pulse transfer circuit 1240 transfers the word line pulse RowCK generated by the word line pulse generator 1520 to the selected row. If the row address decoder 1220 selects the word line WLn, the word line pulse RowCK provided from the word line pulse generator 1520 will be transmitted to the selected word line WLn. The pulse transfer circuit 1240 may include a NAND gate and an inverter corresponding to each row.

The sense amplifier 1320 and the write driver 1340 are provided as part of the data input/output circuit 1300. The sense amplifier 1320 senses data of the selected bit cell in response to the sensing enable signal SA_EN. The output of SA 1320 is output data, Dout. That is, the sense amplifier 1320 detects the level change of the bit line pair (BLT, BLC) developed from the bit cell of the selected row during a read operation. During a write operation, the write driver 1340 transfers input data Din to the selected bit cell via the bit line pair (BLT, BLC). The multiplexer 1420 selects one of a plurality of bit line pairs in response to the column selection signal (/YSEL) provided from the column decoder 1400 (see FIG. 1). Dout and Din are examples of the FIG. 1 signal DATA flowing respectively out and into the data input/output circuit 1300.

The word line pulse generator 1520 may include a pulse generation circuit 1522, an inverter 1524, a row address tracking circuit 1526, a dummy line 1527, a NAND gate 1528, an inverter INV, and a column tracker CT.

Pulse generation circuit 1522 is activated depending on the access mode. For example, when the write enable signal /WEN or the read enable signal /REN is activated, the pulse generation circuit 1522 generates the first pulse signal ICK based on the clock signal CK. The first pulse signal ICK is transmitted to the inverter 1524 and the NAND gate 1528, respectively.

The inverter 1524 includes a pull-up transistor M1 and a pull-down transistor M2. The pull-up transistor M1 may be formed as a PMOS transistor, and the pull-down transistor M2 may be formed as an NMOS transistor. In particular, the pull-down transistor M2 of the inverter 1524 is connected to the row address tracking circuit 1526. Accordingly, the characteristics of the pull-down operation of the inverter 1524 may vary depending on the row address R_ADDR. For example, if a far cell is selected and a large resistance is tracked by the row address tracking circuit 1526, the pull-down speed of inverter 1524 is reduced. As a result, the level drop speed of the output node DBL of the inverter 1524 will also decrease. When the level drop speed of the output node DBL slows, the pulse width of the word line pulse RowCK output through the NAND gate 1528 and the inverter INV increases.

On the other hand, if a near cell is selected and a relatively small resistance is tracked by the row address tracking circuit 1526, the pull-down speed of inverter 1524 increases. Accordingly, the level drop rate of the output node DBL of the inverter 1524 will also increase. As the level drop speed of the output node DBL increases, the pulse width of the word line pulse RowCK output through the NAND gate 1528 and the inverter INV decreases.

The row address tracking circuit 1526 includes a plurality of selection transistors DT1 to DTn that share a drain. The drain of each of the plurality of shared selection transistors DT1 to DTn is connected to the source of the pull-down transistor M2. A metal line may be formed connecting the source of the pull-down transistor M2 and each of the plurality of selection transistors DT1 to DTn. When the row address R_ADDR activates the word line WL1 to select a near cell, the selection transistor DT1 is turned on. Row address tracking circuit 1526 can then provide a relatively small pull-down resistance to inverter 1524. On the other hand, when the row address R_ADDR activates the word line WLn to select a far cell, the selection transistor DTn is turned on. Then, the row address tracking circuit 1526 can provide a relatively large pull-down resistance to the inverter 1524.

The dummy line 1527 may be implemented as a dummy wire with a length corresponding to a wire (for example, a metal line) for supplying cell voltage or bit line voltage to the bit cells of the cell array 1100. Capacitors C1 to Cn may be provided to the output node DBL of the inverter 1524 through the dummy line 1527.

The column tracking circuit CT delays the first pulse signal ICK by a time corresponding to the number of columns of the cell array 1100. The column tracking circuit CT may be formed using, for example, wiring such as a word line or a dummy word line. The first pulse signal ICK can be delayed by a time corresponding to the number of columns and transmitted to the inverter 1524 through the column tracking circuit CT.

In the above, the row address tracking function by the word line pulse generator 1520 and the resulting change in pulse width of the word line pulse RowCK were briefly explained. The word line pulse generator 1520 is activated during a write operation or a read operation and generates a word line pulse RowCK with a pulse width corresponding to the input row address R_ADDR. And the word line voltage VWL corresponding to the width of the generated word line pulse RowCK will be supplied to the selected word line.

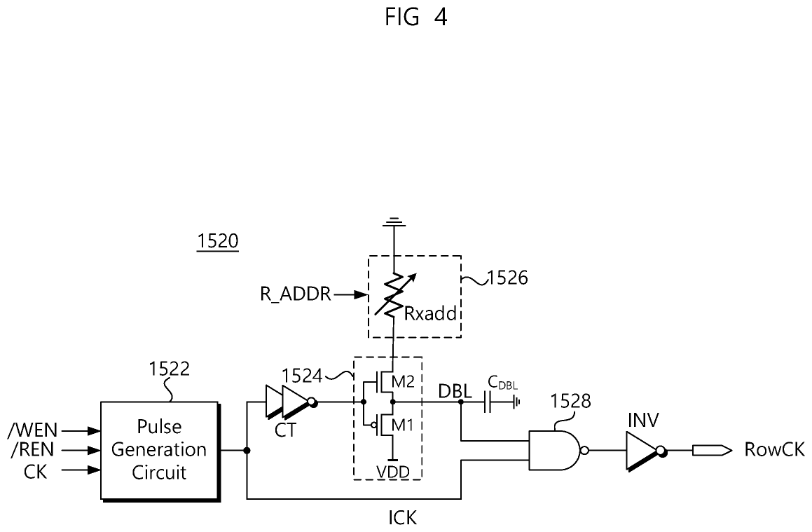

FIG. 4 is a circuit diagram showing the structure of the word line pulse generator shown in FIG. 3. Referring to FIG. 4, the word line pulse generator 1520 includes a pulse generation circuit 1522, a column tracking circuit CT, an inverter 1524, a row address tracking circuit 1526, a NAND gate 1528, and an inverter INV.

Pulse generation circuit 1522 can be activated in any operating mode in which word line pulses RowCK are used. That is, in response to the write enable signal /WEN or the read enable signal /REN in the write operation or read operation mode, the pulse generation circuit 1522 generates the first pulse signal ICK based on the clock signal CK.

The column tracking circuit CT delays the first pulse signal ICK by a time corresponding to the number of columns of the cell array 1100. And the delayed first pulse signal ICK is provided to the inverter 1524.

The inverter 1524 inverts the first pulse signal ICK delayed by the column tracking circuit CT and transmits it to the output node DBL. The inverter 1524 includes a pull-up transistor M1 and a pull-down transistor M2 that receive the first pulse signal ICK at a gate. The pull-down transistor M2 of inverter 1524 is connected to the row address tracking circuit 1526. The amount of charge discharged through the pull-down transistor M2 of the inverter 1524 depends on the size of the tracking resistance Rxadd formed in the row address tracking circuit 1526. That is, the pull-down speed of the inverter 1524 may vary depending on the row address R_ADDR, which determines the resistance of the row address tracking circuit 1526.

The row address tracking circuit 1526 provides a tracking resistance Rxadd of a size corresponding to the row selected by the row address R_ADDR. When the tracking resistance Rxadd is large, the pull-down speed of the inverter 1524 decreases. On the other hand, when the size of the tracking resistance Rxadd is small, the pull-down speed of the inverter 1524 increases.

The level switching speed of the output node DBL of the inverter 1524 is determined according to the tracking resistance Rxadd that varies according to the row address R_ADDR. If the far cell is selected and a relatively large tracking resistance Rxadd is set, the falling time of the output node DBL increases. Accordingly, the pulse width of the word line pulse RowCK corresponding to the logical product AND of the output node DBL and the first pulse signal ICK increases. On the other hand, if a near cell is selected and a relatively small tracking resistance Rxadd is set, the falling time of the output node DBL is reduced. Accordingly, the pulse width of the word line pulse RowCK corresponding to the logical product AND of the output node DBL and the first pulse signal ICK decreases.

Above, an exemplary structure of the word line pulse generator 1520 that generates the word line pulse RowCK whose pulse width varies depending on the row address R_ADDR has been described. It will be well understood that the structure of the word line pulse generator 1520 or the structure of the row address tracking circuit 1526 is not limited to the method shown, and various changes are possible.

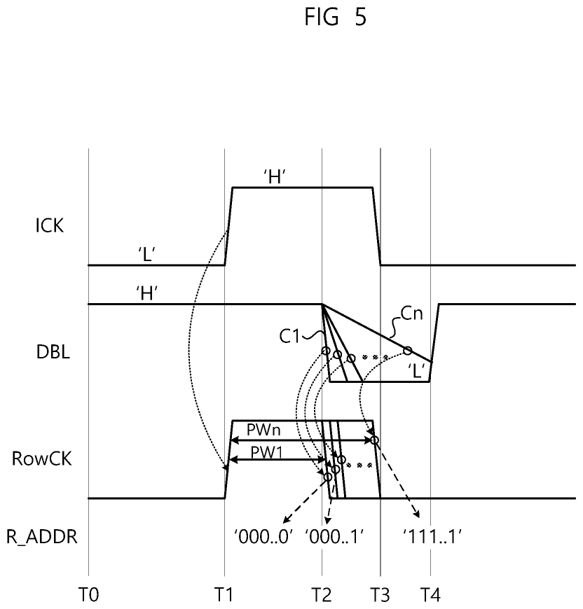

FIG. 5 is a waveform diagram showing the operating characteristics of the word line pulse generator of FIG. 4. Referring to FIG. 5, the pulse width of the word line pulse RowCK output from the word line pulse generator 1520 may be adjusted according to the input row address R_ADDR.

At time TO, it is assumed that the read enable signal /REN or write enable signal /WEN is in the inactivated state. Then, the level of the first pulse signal ICK is generated at a low level ‘L’. And the output node DBL of the inverter 1524 will maintain the high level ‘H’.

At time T1, when the read enable signal /REN or write enable signal /WEN is activated, the pulse generation circuit 1522 (see FIG. 4) sets the first pulse signal ICK to a high level ‘H’. The word line pulse RowCK corresponding to the logical product (or AND operation) between the high level first pulse signal ICK and the output node DBL transitions to the high level ‘H’.

At time T2, the word line is activated by the row address R_ADDR, and the pull-down of the inverter 1524 by the row address tracking circuit 1526 begins. If the row address R_ADDR is set to ‘000 . . . 0’ to select the word line WL1 of the near cell, the tracking resistance Rxadd provided by the row address tracking circuit 1526 is relatively small. Therefore, the pull-down speed of inverter 1524 is set high. Ultimately, the voltage drop at the output node DBL of the inverter 1524 will appear in the form of a curve C1. The word line pulse RowCK may be generated in a form having the narrowest pulse width PW1 by the output node DBL corresponding to the curve CL.

On the other hand, the row address R_ADDR is set to ‘111 . . . 1’ to select the word line WLn of the far cell, the tracking resistance Rxadd provided by the row address tracking circuit 1526 will be set to the maximum value. In this case, the pull-down speed of inverter 1524 is set to the lowest. Ultimately, the voltage drop at the output node DBL of the inverter 1524 will appear in the form of a curve Cn. The word line pulse RowCK can be generated in a form with the widest pulse width PWn by the output node DBL corresponding to the curve Cn. In this way, the pulse width of the word line pulse RowCK can be adjusted to various sizes depending on the row address R_ADDR.

At time T3, the pulse section of the first pulse signal ICK ends. That is, the first pulse signal ICK is recovered from high level to low level ‘L’.

At time T4, following restoration of the first pulse signal ICK, the output node DBL of the inverter 1524 also transitions to the high level ‘H’.

As described above, the word line pulse generator 1520 can generate the word line pulse RowCK whose pulse width is adjusted using the tracking function of the row address R_ADDR. By using the word line pulse RowCK whose pulse width is adjusted according to the row address R_ADDR, the bit line development section of the near cell can be reduced during a read operation. Accordingly, power consumption due to the development level of the bit line that drops excessively when selecting the near cell can be reduced. In addition, when using the word line pulse RowCK whose pulse width is adjusted according to the row address R_ADDR, the distribution of the effective window width of the word line voltage provided to the near cell and far cell can be reduced during the write operation.

In the above, the operating characteristics of the word line pulse generator 1520, which generates the word line pulse RowCK whose pulse width varies depending on the row address R_ADDR, have been described.

Referring to FIG. 3 and FIG. 5, overall, a rising edge of the clock pulse ICK flows through NAND gate 1528 and provides a high input RowCK to the NAND gates in pulse transfer circuit 1240. Inverter 1524 or ICK will act at some time to cause the falling edge of RowCK. For near word lines, this time is shorter. See the line marked C1 in FIG. 5 for the waveform on node DBL. This shorter time provides charge over a shorter time and using an appropriate amount of energy for the near word line to act on the bit cell latch of FIG. 2. For far word lines, the time is longer before inverter 1524 acts. See the line marked Cn in FIG. 5. However, the falling edge of pulse ICK may cause the output of NAND gate 1528 to change before Cn has been pulled down. The longer time provides more charge in order to assure that the bit cell latch of FIG. 2 changes state as required. Inverter 1544 receives an asserted signal (low) from a drain of a selection transistor of 1526 connected to a word line being driven high by the row address decoder 1220. There is a delay of this asserted signal depending on a distance to the driven word line. A delayed version of ICK is fed to a gate line of inverter 1524. When the asserted signal from the drain of the selection transistor pulls down the input to inverter 1524, DBL is driven low until the end of the clock pulse which has travelled through the column tracking circuit CT.

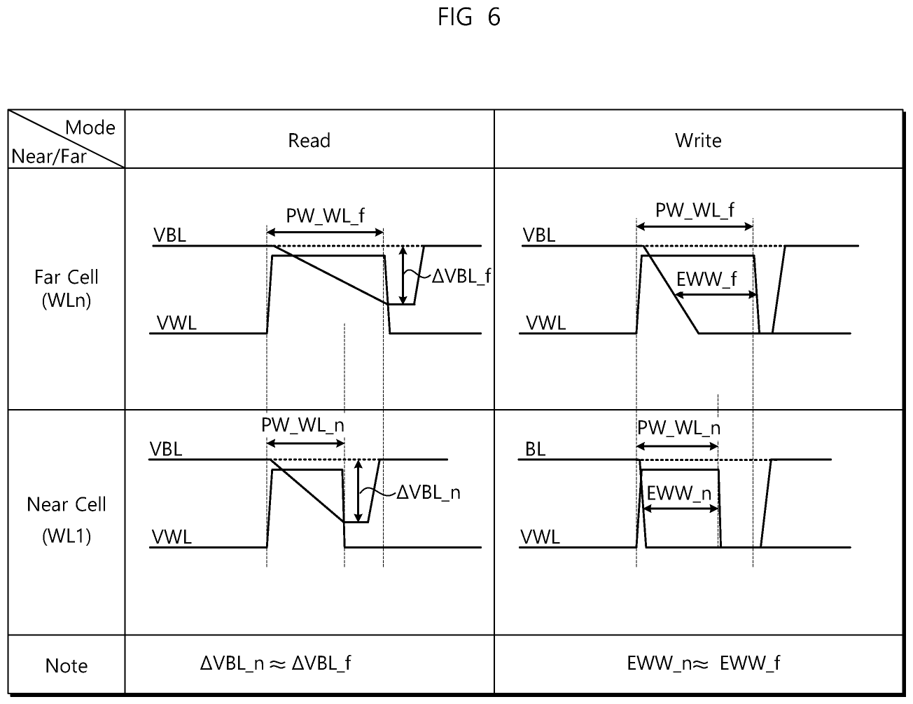

FIG. 6 is a table showing the effect of reducing power consumption by the word line pulse RowCK. Referring to FIG. 6, changes in word line voltage VWL and bit line voltage VBL in each far cell and near cell during read and write operations are shown. Here, a far cell will be a bit cell connected to the word line WLn, and a near cell will be a bit cell connected to the word line WL1. However, near cell and far cell are not limited to examples of the present disclosure.

During a read operation, when a word line WLn for selecting a far cell is selected, a word line voltage VWL having a pulse width PW_WL_f corresponding to the word line pulse RowCK will be provided to the selected bit cell. Then, the bit line pair (BLT, BLC) is developed according to the data status of the bit cell. For example, the voltage of the bit line BLT indicated by a dotted line may be maintained, and the voltage of the complementary bit line BLC may be developed by the first voltage difference ΔVBL_f Since the distribution resistance of the complementary bit line BLC is relatively large depending on the selection of the word line WLn, the development speed of the complementary bit line BLC is relatively slow. According to an embodiment, the word line voltage VWL with a relatively wide pulse width PW_WL_f can be provided, and as a result, a read margin can be secured.

On the other hand, when the word line WL1 for selecting a near cell is selected during a read operation, the word line pulse RowCK reflecting the row address tracking function will be generated. And the word line voltage VWL having a pulse width PW_WL_n corresponding to the word line pulse RowCK will be provided to the selected bit cell. Then, the bit line pair (BLT, BLC) is developed according to the data status of the bit cell. For example, the voltage of the bit line BLT indicated by a dotted line may be maintained, and the voltage of the complementary bit line BLC may be developed by the second voltage difference ΔVBL_n. Since the distribution resistance of the complementary bit line BLC is relatively small depending on the selection of the word line WL1 corresponding to the near cell, the development speed of the complementary bit line BLC is relatively fast compared to the far cell. Accordingly, as the word line voltage VWL having a relatively narrow pulse width PW_WL_n is provided, power consumption due to excessive reduction of the bit line develop level can be prevented. Even if the development speed of the bit line is fast depending on the word line voltage VWL of the pulse width PW_WL_n, the time for developing the bit line may be reduced. Accordingly, the second voltage difference ΔVBL_n, which is the develop level of the bit line in the near cell, may be set to be the same or similar to the first voltage difference ΔVBL_f, which is the develop level of the bit line in the far cell.

During a write operation, a word line voltage VWL reflecting the row address tracking function is used. When a word line (e.g., WLn) for selecting a far cell is selected, a word line voltage VWL having a pulse width PW_WL_f corresponding to the word line pulse RowCK will be provided to the selected bit cell. Then, the write driver 1340 (see FIG. 3) transfers write data to the selected bit cell through the bit line pair (BLT, BLC). At this time, the bit line voltage to which the write data corresponding to the low level ‘L’ is delivered drops to the low level. The voltage drop rate of the far cell is lower than that of the near cell because the distributed resistance of the bit line is large. That is, the slope of the bit line voltage (solid line) is relatively gentle. Accordingly, the time at which write data is written to the latch of the bit cell will correspond to the effective write window EWW_f shown.

On the other hand, when a word line (for example, WL1) for selecting a near cell is selected during a write operation, the word line voltage VWL having a pulse width PW_WL_n corresponding to the word line pulse RowCK is applied to the selected bit cell. Then, the write driver 1340 transfers write data to the selected bit cell through the bit line pair (BLT, BLC). At this time, the bit line voltage (solid line) to which the write data corresponding to the low level ‘L’ is delivered drops to the low level. The voltage drop rate of near cells is higher than that of far cells because the distributed resistance of the bit line is small. That is, the slope of the bit line voltage is relatively steep. Accordingly, the time at which write data is written to the latch of the bit cell will correspond to the effective write window EWW_n, as shown.

As described above, the memory device 1000 according to the present disclosure can generate the word line voltage VWL whose pulse width is adjusted using the tracking function of the row address R_ADDR. By using the word line voltage VWL whose pulse width is adjusted according to the row address R_ADDR, excessive development of the bit line that occurs in near cells can be reduced. Accordingly, power consumption due to excessive bit line development occurring in near cells can be reduced. In addition, when using the word line voltage VWL whose pulse width is adjusted according to the row address R_ADDR, the distribution of the effective window width of the word line voltage VWL provided to the near cell and far cell can be reduced during a write operation.

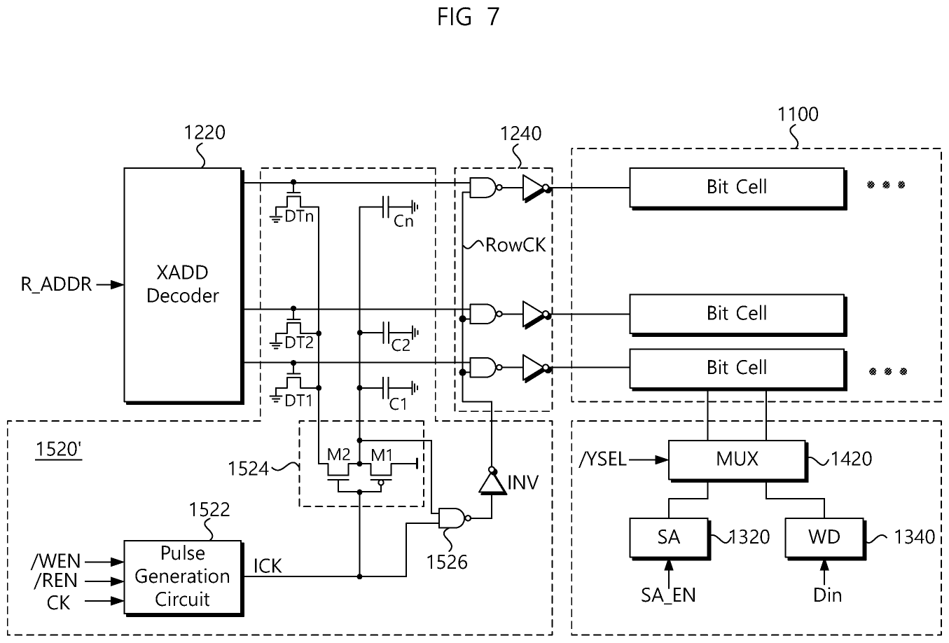

FIG. 7 is a circuit diagram showing the structure of a word line pulse generator according to another embodiment. Referring to FIG. 7, the word line pulse generator 1520′ can generate a word line pulse RowCK with a pulse width that varies according to the row address R_ADDR without using a column tracking circuit CT. The word line voltage VWL is provided to the bit cells of the selected row based on the word line pulse RowCK. Here, the cell array 1100, row address decoder 1220, pulse transfer circuit 1240, multiplexer 1420, sense amplifier 1320, and write driver 1340 are substantially the same as those in FIG. 3. Therefore, description of these will be omitted.

The word line pulse generator 1520′ according to another embodiment has the same configuration as the word line pulse generator 1520 of FIG. 3, except that it does not include the column tracking circuit CT. For example, in the case of the memory device 1000 that applies a fixed number of columns, a separate column tracking function may not be necessary. In this case, the first pulse signal ICK output from the pulse generation circuit 1522 can be immediately provided to the inverter 1524 without delay depending on the number of columns.

In the above, the row address tracking function by the word line pulse generator 1520′ and the resulting change in pulse width of the word line pulse RowCK were briefly explained. The word line pulse generator 1520′ is activated during a write operation or a read operation without a separate column tracking function and can generate a word line pulse RowCK with a pulse width corresponding to the input row address R_ADDR. A word line voltage VWL corresponding to the width of the generated word line pulse RowCK may be supplied to the selected word line.

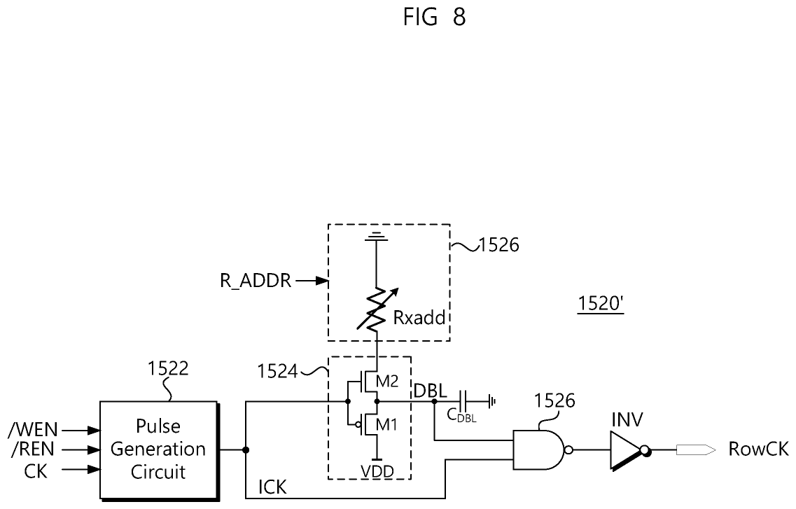

FIG. 8 is a circuit diagram showing the structure of the word line pulse generator shown in FIG. 7. Referring to FIG. 8, the word line pulse generator 1520′ according to another embodiment includes a pulse generation circuit 1522, an inverter 1524, a row address tracking circuit 1526, a NAND gate 1528, and an inverter INV.

The pulse generation circuit 1522 can be activated in any operating mode in which word line pulses RowCK are used. That is, in the write operation and read operation mode to the cell array 1100, the pulse generation circuit 1522 generates the first pulse signal ICK based on the clock signal CK in response to the write enable signal /WEN or the read enable signal /REN, respectively.

The inverter 1524 inverts the first pulse signal ICK and transmits it to the output node DBL. The inverter 1524 includes a pull-up transistor M1 and a pull-down transistor M2 that receive the first pulse signal ICK at a gate. The pull-down transistor M2 of inverter 1524 is connected to the row address tracking circuit 1526. The amount of charge discharged through the pull-down transistor M2 of the inverter 1524 depends on the size of the tracking resistance Rxadd formed in the row address tracking circuit 1526. That is, the pull-down speed of the inverter 1524 may vary depending on the row address R_ADDR, which determines the resistance of the row address tracking circuit 1526.

The row address tracking circuit 1526 provides a tracking resistance Rxadd of a size corresponding to the row selected by the row address R_ADDR. When the tracking resistance Rxadd is large, the pull-down speed of the inverter 1524 decreases. On the other hand, when the size of the tracking resistance Rxadd is small, the pull-down speed of the inverter 1524 increases.

The level switching speed of the output node DBL of the inverter 1524 is determined according to the tracking resistance Rxadd that varies according to the row address R_ADDR. If a far cell is selected and a relatively large tracking resistance Rxadd is set, the falling time of the output node DBL increases. Accordingly, the pulse width of the word line pulse RowCK corresponding to the logical product (or AND operation) of the output node DBL and the first pulse signal ICK increases. On the other hand, if a near cell is selected and a relatively small tracking resistance Rxadd is set, the falling time of the output node DBL is reduced. Accordingly, the pulse width of the word line pulse RowCK corresponding to the logical product (or AND operation) of the output node DBL and the first pulse signal (ICK) decreases.

Above, an exemplary structure of the word line pulse generator 1520′ that generates the word line pulse RowCK whose pulse width varies according to the row address R_ADDR has been described. It will be well understood that the structure of the word line pulse generator 1520′ or the structure of the row address tracking circuit 1526 is not limited to the method shown, and various changes are possible.

FIG. 9 is a circuit diagram showing the structure of a write assistance pulse generator according to an embodiment. Referring to FIG. 9, the write assist pulse generator 1540 may generate a write assist pulse WAST_EN having a pulse width that varies depending on the row address R_ADDR. Using the write assist pulse WAST_EN, the write assist circuit 1360 can supply a cell voltage VDDA with a write assist function to the bit cells of the selected row. The write assist pulse generator 1540 may be provided as part of the control logic circuit 1500 of FIG. 1.

The cell array 1100 includes a plurality of bit cells arranged in rows and columns. A sub power line SPL may be formed in a direction parallel to the bit line to transfer a cell voltage VDDA with a write assistance function to the bit cells. When the cell voltage VDDA is supplied from the write assist circuit 1360, write performance is affected by the resistance RVDDA caused by the sub power line SPL.

By applying the write assist pulse WAST_EN whose pulse width is adjusted according to the row address R_ADDR, changes in the write assist voltage of the near cell and far cell can be controlled to be constant. In other words, the drop of the cell voltage VDDA of the near cell can be set to be equal to or smaller than that of the far cell during a write operation through the write assist pulse WAST_EN whose pulse width is adjusted according to the row address R_ADDR. Accordingly, power consumption caused by a drop in the cell voltage VDDA of the near cell can be reduced.

A row address decoder 1220 and a pulse transfer circuit 1240 are included in the row decoder 1200. The row address decoder 1220 decodes the input row address R_ADDR and activates the selected word line. For example, when the row address R_ADDR corresponds to the word line WL2, the row address decoder 1220 sets the word line WL2 to the high level ‘H’ and the remaining word lines WL1, WL3 to WLn to the low level ‘L’. In addition, when the selected word line is activated, one of the plurality of selection transistors DT1 to DTn of the row address tracking circuit 1546 connected to the selected word line may be turned on.

The pulse transfer circuit 1240 transfers the word line pulse RowCK generated by the word line pulse generator 1520 (see FIG. 3) to the bit cells of the selected row. If the row address decoder 1220 activates the word line WLn, the word line pulse RowCK provided from the word line pulse generator 1520 will be transmitted to the selected bit cell. The pulse transfer circuit 1240 may include a NAND gate and an inverter corresponding to each row.

The write assist pulse generator 1540 may include a pulse generation circuit 1542, an inverter 1544, a row address tracking circuit 1546, a dummy line 1547, a NAND gate 1548, and an inverter INV.

The pulse generation circuit 1542 is activated depending on the access mode. For example, when the write enable signal /WEN is activated, the pulse generation circuit 1542 generates the second pulse signal WAST based on the clock signal CK. The second pulse signal WAST is transmitted to the inverter 1544 and the NAND gate 1548, respectively.

Inverter 1544 includes a pull-up transistor M3 and a pull-down transistor M4. The pull-up transistor M3 may be formed as a PMOS transistor, and the pull-down transistor M4 may be formed as an NMOS transistor. In particular, the pull-down transistor M4 of the inverter 1544 is connected to the row address tracking circuit 1546. Accordingly, the pull-down operation of the inverter 1544 may vary depending on the row address R_ADDR. For example, if a far cell is selected and a large resistance is tracked by the row address tracking circuit 1546, the pull-down speed of inverter 1544 is reduced. Accordingly, the level drop rate of the output node DBL of the inverter 1544 will also decrease. When the level drop speed of the output node DBL slows down, the pulse width of the write assistance pulse WAST_EN output through the NAND gate 1548 and the inverter INV increases.

On the other hand, if a near cell is selected and a relatively small resistance is tracked by the row address tracking circuit 1546, the pull-down speed of inverter 1544 increases. Accordingly, the level drop speed of the output node DBL of the inverter 1544 will also increase. As the level drop speed of the output node DBL increases, the pulse width of the write assistance pulse WAST_EN output through the NAND gate 1548 and the inverter INV decreases.

The row address tracking circuit 1546 includes a plurality of selection transistors DT1 to DTn that share a drain. The drain of each of the plurality of shared selection transistors DT1 to DTn is connected to the source of the pull-down transistor M4. When the row address R_ADDR activates the word line WL1 to select the near cell, the selection transistor DT1 is turned on. Row address tracking circuit 1546 can then provide a relatively small pull-down resistor to inverter 1544. On the other hand, when the row address R_ADDR activates the word line WLn to select the far cell, the selection transistor DTn is turned on. The row address tracking circuit 1546 can then provide a relatively large pull-down resistance to the inverter 1544.

The dummy line 1547 is implemented as a dummy wire corresponding to a wire (for example, a metal line) for supplying a cell voltage VDDA with a write assistance function to the bit cells of the cell array 1100. Capacitances C1 to Cn corresponding to the bit line or sub power line SPL may be reflected in the output node DWAST of the inverter 1544 through the dummy line 1547.

The write assist circuit 1360 provides a cell voltage VDDA to the bit cells of the selected row in response to the write assist pulse WAST_EN. When the write assistance pulse WAST_EN and the column selection signal /YSEL are activated, the AND gate 1362 transmits a pulse signal corresponding to the write assistance pulse WAST_EN to the inverter 1364. The inverter 1364 will transfer the cell voltage VDDA, which is the inverted write assist pulse WAST_EN, to the selected bit cell. At this time, a drop in the cell voltage VDDA of the selected bit cell occurs during the write assistance pulse WAST_EN period, and write performance can be improved. The inverter 1364 may include a pull-up transistor M5, a pull-down transistor M7, and a transistor M6 that is always turned on. It will be well understood that the shape or circuit structure of the inverter 1364 constituting the write assist circuit 1360 is not limited to what is shown and can be changed in various ways.

The memory device 1000 may further include a word line pulse generator 1520 (see FIG. 3), a sense amplifier 1320, or a write driver 1340.

In the above, the row address tracking function by the write assist pulse generator 1540 and the characteristics of the write assist pulse WAST_EN whose pulse width is adjusted accordingly have been described. The write assist pulse generator 1540 is activated during a write operation and generates a write assist pulse WAST_EN with a pulse width corresponding to the input row address R_ADDR. Additionally, the write assist circuit 1360 may supply the cell voltage VDDA, where a drop occurs, to the selected bit cell in response to the pulse width of the write assist pulse WAST_EN.

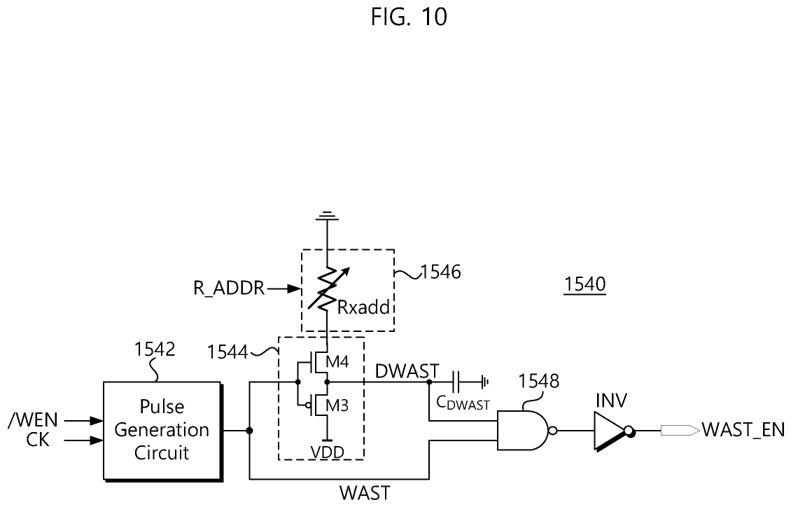

FIG. 10 is a circuit diagram showing the structure of the write assist pulse generator shown in FIG. 9. Referring to FIG. 10, the write assist pulse generator 1540 may include a pulse generation circuit 1542, an inverter 1544, a row address tracking circuit 1546, a NAND gate 1528, and an inverter INV.

The pulse generation circuit 1542 may be activated in a write operation mode. That is, the pulse generation circuit 1542 generates the second pulse signal WAST based on the clock signal CK in response to the write enable signal /WEN activated during a write operation to the cell array 1100.

The inverter 1544 inverts the second pulse signal WAST and transmits it to the output node DWAST. The inverter 1544 includes a pull-up transistor M3 and a pull-down transistor M4 that receive the second pulse signal WAST at a gate. The pull-down transistor M4 of inverter 1544 is connected to row address tracking circuit 1546. The amount of charge discharged through the pull-down transistor M4 of the inverter 1544 depends on the size of the tracking resistance Rxadd formed in the row address tracking circuit 1546. That is, the pull-down speed of the inverter 1544 may vary depending on the row address R_ADDR, which determines the resistance of the row address tracking circuit 1546.

The row address tracking circuit 1546 provides the tracking resistance Rxadd of a size corresponding to the row selected by the row address R_ADDR. When the tracking resistance Rxadd is large, the pull-down speed of the inverter 1544 decreases. On the other hand, when the size of the tracking resistance Rxadd is small, the pull-down speed of the inverter 1544 increases.

The level switching speed of the output node DWAST of the inverter 1544 is determined according to the tracking resistance Rxadd that varies according to the row address R_ADDR. If a far cell is selected and a relatively large tracking resistance Rxadd is set, the voltage drop time of the output node DWAST increases. Accordingly, the pulse width of the write assistance pulse WAST_EN corresponding to the logical product (or AND operation) of the output node DWAST and the second pulse signal WAST increases. On the other hand, when a near cell is selected and a relatively small tracking resistance Rxadd is set, the voltage drop time of the output node DWAST decreases. Accordingly, the pulse width of the write assistance pulse WAST_EN corresponding to the logical product (or AND operation) of the output node DWAST and the second pulse signal WAST decreases.

Above, an exemplary structure of the write assist pulse generator 1540 that generates the write assist pulse WAST_EN whose pulse width varies depending on the row address R_ADDR has been described. It will be well understood that the structure of the write assist pulse generator 1540 or the structure of the row address tracking circuit 1546 is not limited to the method shown, and various changes are possible.

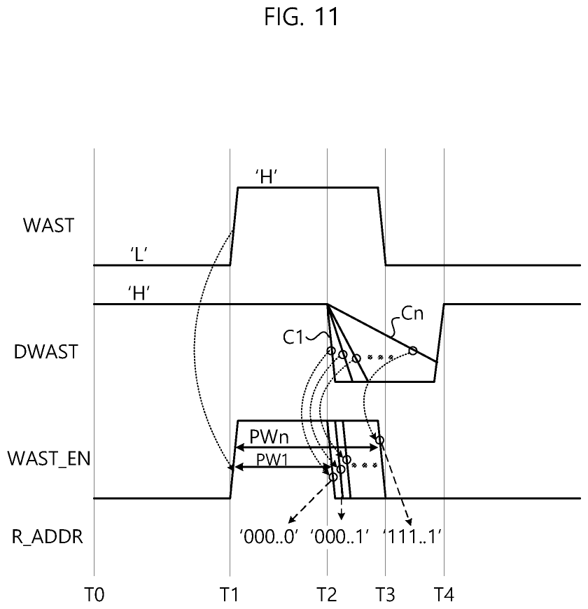

FIG. 11 is a waveform diagram showing the operating characteristics of the write assist pulse generator of FIG. 10. Referring to FIG. 11, the pulse width of the write assist pulse WAST_EN output from the write assist pulse generator 1540 can be freely adjusted according to the input row address R_ADDR.

At time TO, it is assumed that the write enable signal /WEN is in a deactivated state. Then, the level of the second pulse signal WAST is generated at a low level ‘L’. And the output node DWAST of the inverter 1544 will maintain the high level ‘H’.

At time T1, when the write enable signal /WEN is activated, the pulse generation circuit 1542 (see FIG. 10) transitions the second pulse signal WAST to the high level ‘H’. The write assistance pulse WAST_EN corresponding to the logical product (or AND operation) of the high level second pulse signal WAST and the output node DWAST transitions to the high level ‘H’.

At time T2, the word line is activated by the row address R_ADDR, and the pull-down operation of the inverter 1544 by the row address tracking circuit 1546 begins. If the row address R_ADDR is set to ‘000 . . . 0’ to select the word line WL1 of the near cell, the tracking resistance Rxadd provided by the row address tracking circuit 1546 is relatively small. Accordingly, the pull-down speed of inverter 1544 is set high. Ultimately, the voltage drop at the output node DWAST of the inverter 1544 will appear in the form of a curve C1. The write assistance pulse WAST_EN may be generated in a form having the narrowest pulse width PW1 by the output node DWAST voltage corresponding to the curve CL.

On the other hand, the row address R_ADDR is set to ‘111 . . . 1’ to select the word line WLn of the far cell, the tracking resistance Rxadd provided by the row address tracking circuit 1546 will be set to a relatively maximum value. In this case, the pull-down speed of inverter 1544 is set to the lowest. Ultimately, the voltage drop at the output node DWAST of the inverter 1544 will appear in the form of a curve Cn. The write assistance pulse WAST_EN may be generated in a form having the widest pulse width PWn by the output node DWAST corresponding to the curve Cn. In this way, the pulse width of the write assist pulse WAST_EN can be adjusted to various sizes depending on the row address R_ADDR.

At time T3, the pulse section of the second pulse signal WAST ends. That is, the second pulse signal (WAST) is restored from the high level ‘H’ to the low level ‘L’.

At time T4, following restoration of the second pulse signal WAST, the level of the output node DWAST of the inverter 1524 also transitions to the high level ‘H’.

As described above, the write assist pulse generator 1540 can generate a write assist pulse WAST_EN whose pulse width is adjusted using the tracking function of the row address R_ADDR. By using the write assist pulse WAST_EN, whose pulse width is adjusted according to the row address R_ADDR, the size of the drop in the cell voltage VDDA that occurs in the near cell during a write operation can be reduced. Accordingly, power consumption due to excessively low cell voltage VDDA can be reduced.

Above, an exemplary structure of the write assist pulse generator 1540 that generates the write assist pulse WAST_EN whose pulse width varies depending on the row address R_ADDR has been described. It will be well understood that the structure of the write assist pulse generator 1540 or the structure of the row address tracking circuit 1546 is not limited to the method shown, and various changes are possible.

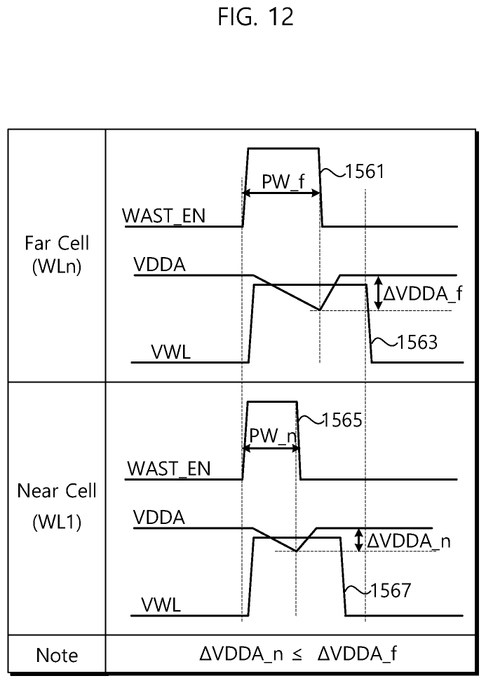

FIG. 12 is a table showing the power reduction effect by the write assist pulse WAST_EN. Referring to FIG. 12, changes in the write assistance pulse WAST_EN, word line voltage VWL, and cell voltage VDDA in each far cell and near cell during a write operation are shown.

When the write enable signal /WEN is activated and the word line WLn for selecting a far cell is selected, the write assist pulse generator 1540 generates a write assist pulse (WAST_EN, 1561). In addition, the word line voltage VWL will be applied to the word line WLn as shown in waveform 1563. Then, the write assist circuit 1360 (see FIG. 9) drops the cell voltage VDDA for a time corresponding to the pulse width PW_f of the write assist pulse (WAST_EN, 1561). At this time, the magnitude of the cell voltage VDDA that drops during the time corresponding to the pulse width PW_f may be expressed as the first voltage difference ΔVDDA_f.

On the other hand, when the write enable signal /WEN is activated during a write operation on a near cell connected to the word line WL1, the write assist pulse generator 1540 generates a write assist pulse WAST_EN of the pulse width (PW_n, 1565). In addition, the word line voltage VWL will be applied to the word line WL1 as shown in waveform 1567. Then, the write assist circuit 1360 will drop the cell voltage VDDA for a time corresponding to the pulse width PW_n of the write assist pulse WAST_EN 1565. At this time, the magnitude of the cell voltage VDDA that drops during the time corresponding to the pulse width PW_n may be expressed as the second voltage difference ΔVDDA_n.

Here, the cell voltage drop size ΔVDDA_f of the far cell may be greater than or equal to the cell voltage drop size ΔVDDA_n of the near cell. The reason why this is possible is because the write assist pulse WAST_EN whose pulse width varies depending on the row address R_ADDR is generated. Ultimately, power consumption due to excessive cell voltage VDDA drop of the near cell during a write operation can be prevented by the write assist pulse generator 1540.

An example or write assist is now provided considering the bit cell of FIG. 2 and the lowering of VDDA for the far cell (top of FIG. 12). In this example, PU1 is initially on and needs to be turned off to flip the bit in the latch. In this example, the bit line signal /Nn goes high and this lowers the gate voltage at the PMOS PUL. VDDA has been lowered by ΔVDDA_f. Nn is low, and the current through PU1 is now less because VDDA is less by ΔVDDA_f. Thus PU1 is assisted in turning off by the voltage ΔVDDA_f. At the same time, PD2 (an NMOS transistor) is on and needs to turn off. Nn is low and PD2 has few electrons (NMOS majority carriers) in its channel. PU2 is tending to turn on due to the low value of Nn, conducting VDDA to the drain of PD2. The lower VDDA value with the low gate voltage of PD2 tends to turn PD2 off more quickly, as desired to write the value to the latch. Thus this feature provides write assist.

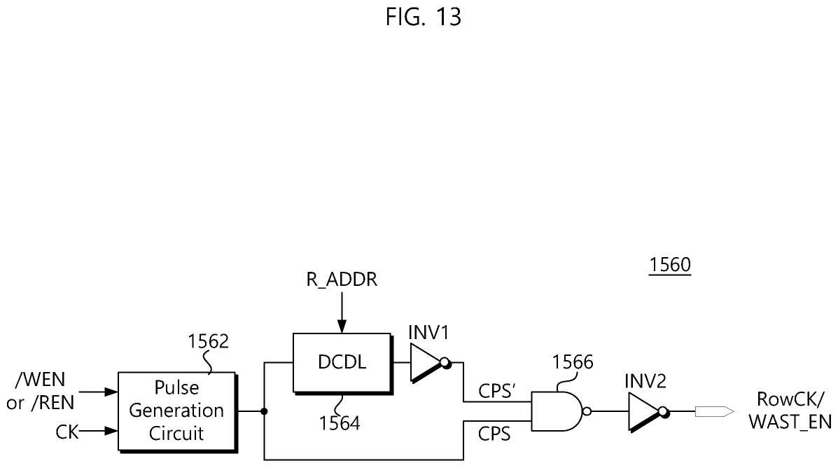

FIG. 13 is a circuit diagram showing another implementation method of the word line pulse generator or the write assist pulse generator with the row address tracking function. Referring to FIG. 13, the row address tracking pulse generator 1560 includes a pulse generation circuit 1562, a digital control delay line 1564, a first inverter INV1, a NAND gate 1566, and a second inverter INV2.

The pulse generation circuit 1562 may be activated in a write operation or a read operation mode. That is, in the write operation or read operation mode to the cell array 1100, the pulse generation circuit 1562 generates a pulse signal CPS based on the clock signal CK in response to the write enable signal /WEN or the read enable signal /REN.

The digital control delay line (DCDL) 1564 reflects the delay corresponding to the row address R_ADDR in the input pulse signal CPS. That is, the digital control delay line 1564 can switch the pulse signal CPS to pass through a resistance or impedance corresponding to the row address R_ADDR. Through this, the row address R_ADDR tracking function can be implemented without using a separate dummy metal line.

The first inverter INV1 inverts the output of the digital control delay line 1564 and transmits it to the NAND gate 1566. The NAND gate 1566 and the second inverter INV2 perform logical multiplication operation on the output the pulse signal CPS directly transmitted from the pulse generation circuit 1562 and a delayed pulse signal CPS' via the digital control delay line 1564 and the first inverter INV1. The NAND gate 1566 and the second inverter INV2 may output the word line pulse RowCK or a write assistance pulse WAST_EN as a result of the logical multiplication operation.

The above describes the row address tracking pulse generator 1560, which uses the digital control delay line 1564 to generate the word line pulse RowCK or the write assist pulse WAST_EN whose pulse width varies depending on the row address R_ADDR. When the row address tracking pulse generator 1560 is applied, the word line pulse RowCK or the write assist pulse WAST_EN can be easily generated without using a separate dummy metal line.

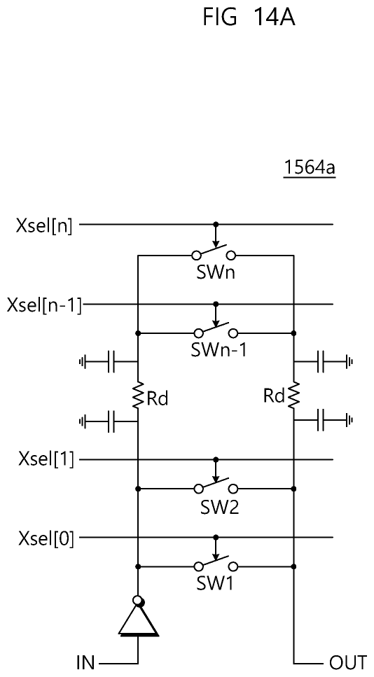

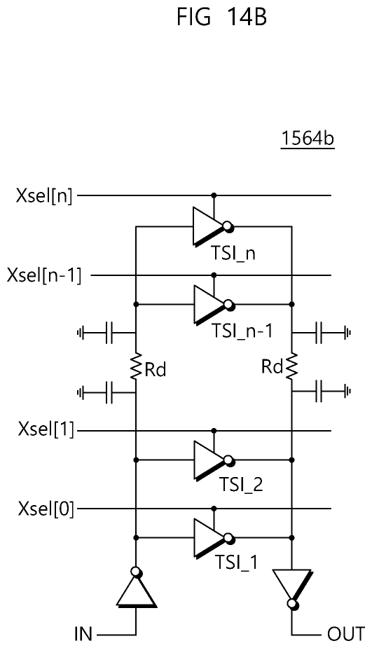

FIG. 14A and FIG. 14B are circuit diagrams showing embodiments of the digital control delay line of FIG. 13, respectively. FIG. 14A shows a digital control delay line 1564a configured using a switch, and FIG. 14b shows a digital control delay line 1564b configured using a tristate Inverter.

Referring to FIG. 14A, the digital control delay line 1564a includes switches SW1 to SWn corresponding to each of a plurality of rows Xsel[i]. The switch of one row Xsel[i]selected by the row address R_ADDR among the plurality of rows is turned on. Then, the input signal will be transmitted to the output side through the resistance path corresponding to the selected row Xsel[i].

Referring to FIG. 14B, the digital control delay line 1564b includes tristate Inverters TSI_1 to TSI_n corresponding to each of a plurality of rows Xsel[i]. The digital control delay line 1564b can be implemented by replacing the switches SW1 to SWn of the digital control delay line 1564a with tristate Inverters TSI_1 to TSI_n and adding an inverter to the output terminal.

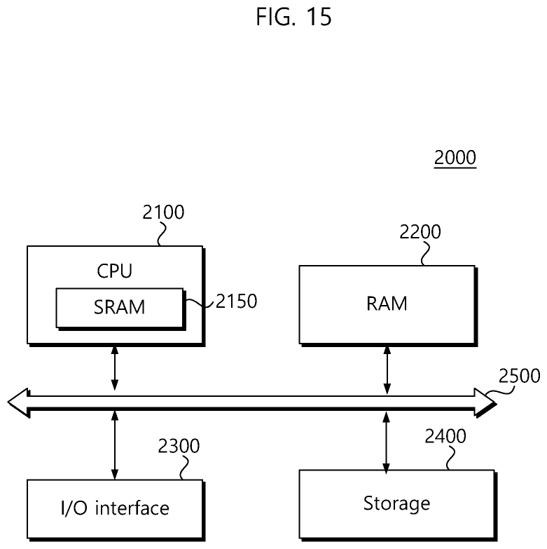

FIG. 15 is a block diagram illustrating the hardware structure of a mobile device including the memory device. Referring to FIG. 15, the mobile device 2000 may include a CPU 2100, RAM 2200, an input/output interface 2300, a storage 2400, and a system bus 2500. Here, the mobile device 2000 may be a computer system or a workstation.

The CPU 2100 executes software (application programs, operating systems, device drivers) to be executed on the mobile device 2000. CPU 2100 will execute an operating system (OS) loaded into RAM 2200. The CPU 2100 will execute various application programs to be run based on the operating system OS. The CPU 2100 may include the SRAM 2150 used as a cache memory. SRAM 2150 may be the memory device of FIG. 1 that includes a word line pulse generator or a write assist pulse generator with a row address tracking function. Therefore, when using the SRAM 2150 as a cache memory, high power efficiency can be achieved in a mobile environment.

The operating system OS or application programs will be loaded into the RAM 2200. When the mobile device 2000 boots, the OS image stored in the storage 2400 will be loaded into the RAM 2200 based on the boot sequence. All input/output operations of the mobile device 2000 may be supported by an operating system OS. Likewise, application programs selected by the user or to provide basic services may be loaded into the RAM 2200. The RAM 2200 may be volatile memory such as Static Random Access Memory (SRAM) or Dynamic Random Access Memory (DRAM), or non-volatile memory such as PRAM, MRAM, ReRAM, FRAM, or NOR flash memory.

The input/output interface 2300 controls user input and output from user interface devices. For example, the input/output interface 2300 may include a keyboard, touchpad, and monitor to receive commands or data from the user.

Storage 2400 is provided as a storage medium of the mobile device 2000. Storage 2400 may be provided as a memory card (MMC, eMMC, SD, MicroSD, etc.) or hard disk drive (HDD). The storage 2400 may include NAND flash memory with large storage capacity. Alternatively, the storage 2400 may include next-generation non-volatile memory such as PRAM, MRAM, ReRAM, and FRAM.

The system bus 2500 is a bus for providing a network inside the mobile device 2000. The CPU 2100, RAM 2200, input/output interface 2300, and storage 2400 are connected through the system bus 2500 and can exchange data with each other. However, the configuration of the system bus 2500 is not limited to the above description, and may further include mediation means for efficient management.

The above mobile device 2000 may include an SRAM 2150 including a word line pulse generator or a write assist pulse generator with a row address tracking function according to the present disclosure. Accordingly, the mobile device 2000 can provide high low-power performance in a mobile environment.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a cell array comprising a plurality of static random-access memory (SRAM) cells;
a row decoder configured to drive a plurality of word lines of the plurality of SRAM cells based on a row address;
a data input/output circuit connected to a plurality of bit lines of the cell array and connected to a sub-power line configured to supply cell voltage to the plurality of SRAM cells; and
a word line pulse generator configured to generate a word line pulse with a first pulse width that varies based on the row address and to provide the word line pulse to the row decoder.

2. The memory device of claim 1, wherein the word line pulse generator comprises:
a first pulse generation circuit configured to generate a first pulse signal based on a write enable signal or a read enable signal;
a first inverter configured to invert the first pulse signal;
a first row address tracking circuit configured to adjust a pull-down speed of the first inverter based on the row address; and
a first logic gate unit configured to perform logical multiplication operation on an output of the first inverter and the first pulse signal to output the word line pulse.

3. The memory device of claim 2, wherein the first row address tracking circuit comprises a plurality of first selection transistors, each of the plurality of first selection transistors having a drain which is connected to a pull-down transistor of the first inverter, a gate which is connected to a corresponding word line of the plurality of word lines, and a source which is connected to ground.

4. The memory device of claim 3, further comprising a metal line connecting the drain of each of the plurality of first selection transistors to a source of the pull-down transistor.

5. The memory device of claim 2, wherein the word line pulse generator comprises a dummy line extending in a bit line direction at an output terminal of the first inverter.

6. The memory device of claim 2, wherein the word line pulse generator comprises a column tracking circuit configured to delay the first pulse signal based on a number of columns of the cell array to transmit the first pulse signal with the delay to the first inverter.

7. The memory device of claim 1, further comprising:
a write assist pulse generator configured to generate a write assist pulse with a second pulse width varying based on the row address; and
a write assist circuit configured to provide a write assist voltage to a selected SRAM cell through a sub power line based on the write assist pulse during a write operation.

8. The memory device of claim 7, wherein the write assist pulse generator comprises:
a second pulse generation circuit configured to generate a second pulse signal in response to the write enable signal;
a second inverter configured to invert the second pulse signal;
a second row address tracking circuit configured to adjust a pull-down speed of the second inverter based on the row address; and
a second logic gate unit configured to perform logical product operation on an output of the second inverter and the second pulse signal to output the write assist pulse.

9. The memory device of claim 8, wherein the write assist circuit is further configured to lower the cell voltage of the selected SRAM cell during a pulse duration of the write assist pulse.

10. The memory device of claim 9, wherein the second row address tracking circuit comprises a plurality of second selection transistors, each of the plurality of second selection transistors having a drain which is connected to a pull-down transistor of the second inverter, a gate which is connected to a corresponding word line of the plurality of word lines, and a source which is connected to ground.

11. The memory device of claim 10, further comprising a metal line connecting the drain of each of the plurality of second selection transistors to a source of the pull-down transistor of the second inverter.

12. A pulse generator of a static random-access memory (SRAM) device, the pulse generator comprising:
a pulse generation circuit configured to generate a first pulse signal based on a write enable signal or a read enable signal;
a row address tracking circuit configured to generate a second pulse signal by delaying the first pulse signal based on a row address; and
a logic gate unit configured to generate a word line pulse or a write assist pulse of the SRAM device by performing logical multiplication operation of the first pulse signal and the second pulse signal.

13. The pulse generator of claim 12, wherein the row address tracking circuit comprises:
an inverter comprising a pull-up transistor and a pull-down transistor; and
a plurality of selection transistors, each of the plurality of selection transistors having a drain which is connected to a source of the pull-down transistor, a gate which is connected to a corresponding word line of a plurality of word lines, and a source which is grounded.

14. The pulse generator of claim 13, wherein the drain of each of the plurality of selection transistors and the source of the pull-down transistor are connected through a metal line.

15. The pulse generator of claim 12, further comprising a column tracking circuit configured to delay the first pulse signal according to a number of columns of the SRAM device to transmit to the row address tracking circuit.

16. The pulse generator of claim 12, wherein the row address tracking circuit comprises a digital control delay line configured to be switched by the row address.

17. The pulse generator of claim 16, wherein the digital control delay line comprises a switch or a tristate inverter configured to be turned on or off by the row address.

18. A memory device comprising:
a cell array comprising a plurality of static random-access memory (SRAM) cells;
a row decoder configured to drive a plurality of word lines of the plurality of SRAM cells based on a row address;
a data input/output circuit connected to a plurality of bit lines of the cell array;
a write assist circuit configured to supply a cell voltage or a write assist voltage to the plurality of SRAM cells through a sub power line;
a word line pulse generator configured to generate a word line pulse with a first pulse width that varies based on the row address to provide the word line pulse to the row decoder; and
a write assist pulse generator configured to generate a write assist pulse with a second pulse width that varies based on the row address.

19. The memory device of claim 18, wherein the word line pulse generator comprises:
a first pulse generation circuit configured to generate a first pulse signal based on a write enable signal or a read enable signal;
a first inverter configured to invert the first pulse signal;
a first row address tracking circuit configured to adjust a pull-down speed of the first inverter according to the row address; and
a first logic gate unit configured to perform logical multiplication operation on an output of the first inverter and the first pulse signal to generate the word line pulse.

20. The memory device of claim 18, wherein the write assist pulse generator comprises:
a second pulse generation circuit configured to generate a second pulse signal in response to the write enable signal;
a second inverter configured to invert the second pulse signal;
a second row address tracking circuit configured to adjust a pull-down speed of the second inverter based on the row address; and
a second logic gate unit configured to perform logical product operation on an output of the second inverter and the second pulse signal to output the write assist pulse.
